(19) United States
(12) Patent Application Publication
(10) Pub. No.: US 2026/0230066 A1
(43) Pub. Date: Aug. 6, 2026

(54) CLOCK CONTROL DEVICE

(71) Applicant: Sony Semiconductor Solutions Corporation, Kanagawa (JP)

(72) Inventors: Riichi Nishino, Kanagawa (JP); Shuei Morishita, Kanagawa (JP); Masakazu Moro, Kanagawa (JP)

(21) Appl. No.: 19/152,714

(22) PCT Filed: Nov. 8, 2023
(86) PCT No.: PCT/JP23/40290

§ 371 Date: Jul. 31, 2025

(30) Foreign Application Priority Data
Mar. 23, 2023 (JP) 2023-046196

(51) Int. Cl. H03K 5/1252; H03K 5/02; H03K 5/134

(52) U.S. Cl. CPC H03K 5/1252; H03K 5/02; H03K 5/134

(57) ABSTRACT

Jitter added to a clock due to power supply noise is reduced. In one example, a clock control device includes a first inverter that is connected between a first potential and a second potential and is inputted with a clock, a second inverter that is connected between the first potential and the second potential, shares an output with the first inverter, and is inputted with a control signal, a resistor that is connected between at least one of the first potential or the second potential and the first inverter. and a capacitor that is connected between the first potential and the second potential via the resistor. A DCA circuit may include the first inverter, the second inverter, the resistor, and the capacitor, and the DCA circuit may be connected in a plurality of stages.

### TECHNICAL FIELD

The present technology relates to a clock control device. Specifically, the present technology relates to a clock control device using a duty cycle adjust (DCA) circuit.

### BACKGROUND ART

An error in a duty cycle of a clock may cause an increase of jitter in serial communication data output from a driver of a transmitter system in accordance with the clock. In order to suppress an error in the duty cycle of the clock, a DCA circuit that corrects a duty on the basis of a control voltage may be used (see, for example, Non-Patent Document 1).

### CITATION LIST

### Non-Patent Document

Non-Patent Document 1: SOCC 2015, A 20 GHz high speed, low jitter, high accuracy and wide correction range duty cycle corrector|IEEE Conference Publication|IEEE Xplore

### SUMMARY OF THE INVENTION

### Problems to be Solved by the Invention

However, the DCA circuit tends to have low power supply noise resistance, and there has been a strong tendency that jitter is added to a clock to be output due to power supply noise.

The present technology has been made in view of such a situation, and an object thereof is to reduce jitter added to a clock due to power supply noise.

### Solutions to Problems

The present technology has been made to solve the above-described problems, and a first aspect thereof is a clock control device including: a first inverter to which a clock is input; a second inverter that shares an output with the first inverter and is inputted with a control signal; and an RC low-pass filter connected between the first inverter and a power supply. As a result, an effect is provided that power supply noise input to the first inverter is reduced by a filter effect of the RC low-pass filter.

Furthermore, in the first aspect, the RC low-pass filter may include: a resistor connected in series with the first inverter; and a capacitor connected to a connection point between the first inverter and the resistor. As a result, an effect is provided that jitter added to a clock due to power supply noise is effectively reduced.

Furthermore, in the first aspect, the resistor may be provided on each side of a power supply of the first inverter. As a result, an effect is provided that jitter added to a clock due to power supply noise is effectively reduced.

Furthermore, in the first aspect, the resistor may be provided on one side of a power supply of the first inverter. As a result, an effect is provided that jitter added to a clock due to power supply noise is effectively reduced while suppressing an increase in the number of resistors.

Furthermore, in the first aspect, the capacitor may be connected in parallel with the first inverter. As a result, an effect is provided that jitter added to a clock due to power supply noise is effectively reduced.

Furthermore, in the first aspect, the capacitor may be connected in parallel with a series circuit of the first inverter and the resistor. As a result, an effect is provided that jitter added to a clock due to power supply noise is effectively reduced.

Furthermore, in the first aspect, the resistor may be a resistance element, an on-resistor of a field effect transistor, or a series circuit of the resistance element and the on-resistor of the field effect transistor. As a result, an effect is provided that the RC low-pass filter connected to the power supply of the first inverter is formed.

Furthermore, in the first aspect, a duty cycle adjust (DCA) circuit may include the first inverter, the second inverter, and the RC low-pass filter, and the DCA circuit may be connected in a plurality of stages. As a result, an effect is provided that power supply noise input to the DCA circuit is reduced by a low-pass filter effect based on the resistor and the capacitor, while increasing a correction amount of a duty of a clock.

Furthermore, in the first aspect, a differential control signal may be used as a control signal of two of the DCA circuits connected in the plurality of stages. As a result, an effect is provided that in-phase noise is reduced.

Furthermore, in the first aspect, a DCA circuit may include the first inverter, the second inverter, and the RC low-pass filter, and the DCA circuit may be connected in one stage. As a result, an effect is provided that power supply noise input to the DCA circuit is reduced by a low-pass filter effect based on the resistor and the capacitor, while simplifying the configuration of the clock control device.

Furthermore, in the first aspect, there may be further included: a differentiation circuit configured to differentiate an output of the second inverter; an amplifier configured to generate the control signal on the basis of a differentiation output that is output from the differentiation circuit; and a low-pass filter connected to an input of the amplifier. As a result, an effect is provided that a power supply rejection ratio (PSRR) of the control signal approaches 0 dB by connecting a filter capacitor to VDD. Furthermore, an effect is provided that the PSRR of the control signal is reduced by connecting the filter capacitor to VSS.

Furthermore, in the first aspect, the low-pass filter may include: a filter resistor in series with an input of the amplifier; and a filter capacitor that is in parallel with an input of the amplifier and is connected to a power supply or ground of the first inverter or both the power supply and the ground. As a result, an effect is provided that the PSRR of the control voltage can be adjusted, and jitter added to a clock due to power supply noise is reduced.

Furthermore, in the first aspect, a local low-pass filter connected to a gate input of a field effect transistor used for the second inverter may be further included. As a result, an effect is provided that the PSRR of the gate input of the field effect transistor used for the second inverter can be adjusted, and jitter added to a clock due to power supply noise is reduced.

Furthermore, a second aspect of the present technology is a clock control device including: a first inverter to which a clock is input; a second inverter that shares an output with the first inverter and is inputted with a control signal; a differentiation circuit configured to differentiate an output of the second inverter; an amplifier configured to generate the control signal on the basis of a differentiation output that is output from the differentiation circuit; and a low-pass filter connected to an input of the amplifier. As a result, an effect is provided that the PSRR of the control signal approaches 0 dB by connecting filter capacitor to VDD. Furthermore, an effect is provided that the PSRR of the control signal is reduced by connecting the filter capacitor to VSS.

Furthermore, in the second aspect, the low-pass filter may include: a filter resistor in series with an input of the amplifier; and a filter capacitor that is in parallel with an input of the amplifier and is connected to a power supply or ground of the first inverter or both the power supply and the ground. As a result, an effect is provided that the PSRR of the control voltage can be adjusted, and jitter added to a clock due to power supply noise is reduced.

Furthermore, in the second aspect, a local low-pass filter connected to a gate input of a field effect transistor used for the second inverter may be further included. As a result, an effect is provided that the PSRR of the gate input of the field effect transistor used for the second inverter can be adjusted, and jitter added to a clock due to power supply noise is reduced.

Furthermore, in the second aspect, a DCA circuit may include the first inverter and the second inverter, and the DCA circuit may be connected in a plurality of stages. Furthermore, the low-pass filter may include: a filter resistor in series with an input of the amplifier; and a filter capacitor that is in parallel with an input of the amplifier and is connected to a power supply or ground of the first inverter or both the power supply and the ground. As a result, an effect is provided that the PSRR of the control voltage can be adjusted while increasing a correction amount of a duty of a clock, and jitter added to a clock due to power supply noise is reduced.

Furthermore, in the second aspect, a differential control signal may be used as a control signal of two of the DCA circuits connected in the plurality of stages. As a result, an effect is provided that in-phase noise is reduced.

Furthermore, in the second aspect, a DCA circuit may include the first inverter, the second inverter, and the RC low-pass filter, and the DCA circuit may be connected in one stage. As a result, an effect is provided that power supply noise input to the DCA circuit is reduced by a low-pass filter effect based on the resistor and the capacitor, while simplifying the configuration of the clock control device.

### BRIEF DESCRIPTION OF DRAWINGS

FIG. 1 is a circuit diagram illustrating a configuration example of a clock control device according to a first embodiment.

FIG. 2 is a graph illustrating KVDD characteristics of the clock control device according to the first embodiment.

FIG. 3 is a circuit diagram illustrating a first configuration example of a DCA circuit according to a second embodiment.

FIG. 4 is a circuit diagram illustrating a second configuration example of the DCA circuit according to the second embodiment.

FIG. 5 is a circuit diagram illustrating a third configuration example of the DCA circuit according to the second embodiment.

FIG. 6 is a circuit diagram illustrating a fourth configuration example of the DCA circuit according to the second embodiment.

FIG. 7 is a circuit diagram illustrating a fifth configuration example of the DCA circuit according to the second embodiment.

FIG. 8 is a circuit diagram illustrating a sixth configuration example of the DCA circuit according to the second embodiment.

FIG. 9 is a circuit diagram illustrating a seventh configuration example of the DCA circuit according to the second embodiment.

FIG. 10 is a circuit diagram illustrating an eighth configuration example of the DCA circuit according to the second embodiment.

FIG. 11 is a circuit diagram illustrating a ninth configuration example of the DCA circuit according to the second embodiment.

FIG. 12 is a circuit diagram illustrating a tenth configuration example of the DCA circuit according to the second embodiment.

FIG. 13 is a circuit diagram illustrating an eleventh configuration example of the DCA circuit according to the second embodiment.

FIG. 14 is a circuit diagram illustrating a first configuration example of a DCA circuit according to a third embodiment.

FIG. 15 is a circuit diagram illustrating a second configuration example of the DCA circuit according to the third embodiment.

FIG. 16 is a circuit diagram illustrating a third configuration example of the DCA circuit according to the third embodiment.

FIG. 17 is a circuit diagram illustrating a fourth configuration example of the DCA circuit according to the third embodiment.

FIG. 18 is a circuit diagram illustrating a fifth configuration example of the DCA circuit according to the third embodiment.

FIG. 19 is a circuit diagram illustrating a sixth configuration example of the DCA circuit according to the third embodiment.

FIG. 20 is a circuit diagram illustrating a seventh configuration example of the DCA circuit according to the third embodiment.

FIG. 21 is a circuit diagram illustrating an eighth configuration example of the DCA circuit according to the third embodiment.

FIG. 22 is a circuit diagram illustrating a ninth configuration example of the DCA circuit according to the third embodiment.

FIG. 23 is a circuit diagram illustrating a tenth configuration example of the DCA circuit according to the third embodiment.

FIG. 24 is a circuit diagram illustrating a configuration example of a clock control device according to a fourth embodiment.

FIG. 25 is a circuit diagram illustrating a configuration example of a clock control device according to a fifth embodiment.

FIG. 26 is a circuit diagram illustrating a configuration example of a clock control device according to a sixth embodiment.

FIG. 27 is a circuit diagram illustrating a configuration example of a clock control device according to a seventh embodiment.

FIG. 28 is a circuit diagram illustrating a configuration example of a clock control device according to an eighth embodiment.

FIG. 29 is a circuit diagram illustrating a configuration example of a clock control device according to a ninth embodiment.

FIG. 30 is a circuit diagram illustrating a configuration example of a clock control device according to a tenth embodiment.

FIG. 31 is a circuit diagram illustrating a configuration example of a clock control device according to an eleventh embodiment.

FIG. 32 is a block diagram illustrating a configuration example of a communication interface according to a twelfth embodiment.

FIG. 33 is a circuit diagram illustrating a first configuration example of a DCA circuit according to a thirteenth embodiment.

FIG. 34 is a circuit diagram illustrating a second configuration example of the DCA circuit according to the thirteenth embodiment.

FIG. 35 is a circuit diagram illustrating a third configuration example of the DCA circuit according to the thirteenth embodiment.

FIG. 36 is a circuit diagram illustrating a fourth configuration example of the DCA circuit according to the thirteenth embodiment.

### MODE FOR CARRYING OUT THE INVENTION

Modes for carrying out the present technology (hereinafter, referred to as embodiments) will be described below. The description will be given in the following order.
1. First Embodiment (an example in which an RC low-pass filter is connected between an inverter to which a clock is input and a power supply, and a low-pass filter is connected to an input of an amplifier that generates a control signal of a DCA circuit)
2. Second Embodiment (an example in which a resistor of an RC low-pass filter connected to a power supply of an inverter to which a clock is input has the same configuration on a high power supply potential side and a low power supply potential side)
3. Third Embodiment (an example in which a resistor of an RC low-pass filter connected to a power supply of an inverter to which a clock is input is different between a high power supply potential side and a low power supply potential side)
4. Fourth Embodiment (an example in which a capacitor of a low-pass filter connected to an input of an amplifier that generates a control signal of a DCA circuit is connected to a low power supply potential)
5. Fifth Embodiment (an example in which a capacitor of a low-pass filter connected to an input of an amplifier that generates a control signal of a DCA circuit is connected to a high power supply potential and a low power supply potential)
6. Sixth Embodiment (an example in which a capacitor of a low-pass filter connected to an input of an amplifier that generates a control signal of a DCA circuit is connected to a high power supply potential and a low power supply potential, and a local low-pass filter is connected to a gate input of a field effect transistor to which the control signal is input)
7. Seventh Embodiment (an example in which a capacitor of a low-pass filter connected to an input of an amplifier that generates a control signal of a DCA circuit is connected to a high power supply potential and a low power supply potential, and a local low-pass filter is connected to a gate input of an N-channel field effect transistor to which the control signal is input)
8. Eighth Embodiment (an example in which a capacitor of a low-pass filter connected to an input of an amplifier that generates a control signal of a DCA circuit is connected to a high power supply potential and a low power supply potential, and a local low-pass filter is connected to a gate input of a P-channel field effect transistor to which the control signal is input)
9. Ninth Embodiment (an example in which a capacitor of a low-pass filter connected to an input of an amplifier that generates a control signal of a DCA circuit is connected to a high power supply potential, and a local low-pass filter is connected to a gate input of an N-channel field effect transistor to which the control signal is input)
10. Tenth Embodiment (an example in which a capacitor of a low-pass filter connected to an input of an amplifier that generates a control signal of a DCA circuit is connected to a low power supply potential, and a local low-pass filter is connected to a gate input of a P-channel field effect transistor to which the control signal is input)
11. Eleventh Embodiment (an example in which, in a one-stage DCA circuit, an RC low-pass filter is connected between an inverter to which a clock is input and a power supply, and a low-pass filter is connected to an input of an amplifier that generates a control signal of the DCA circuit)
12. Twelfth Embodiment (an example in which a duty cycle correction (DCC) circuit is applied to a communication interface)
13. Thirteenth Embodiment (an example in which a plurality of RC low-pass filters is connected between an inverter to which a clock is input and a power supply)

### 1. First Embodiment

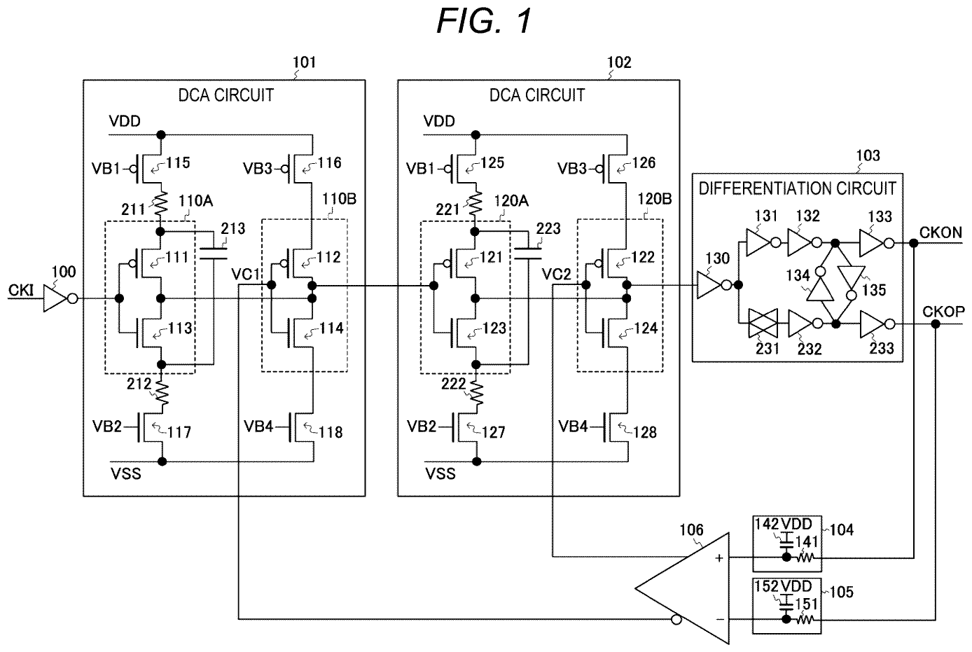

FIG. 1 is a circuit diagram illustrating a configuration example of a clock control device according to a first embodiment.

In the figure, the clock control device corrects a duty cycle of a clock CKI on the basis of control signals VC1 and VC2. The control signals VC1 and VC2 may be differentiated. The clock control device includes DCA circuits 101 and 102, a differentiation circuit 103, low-pass filters 104 and 105, and an amplifier 106.

The DCA circuits 101 and 102 adjust a rising delay time and a falling delay time of the clock CKI on the basis of the respective control signals VC1 and VC2. The DCA circuit 102 is connected at a subsequent stage of the DCA circuit 101. As a power supply of each of the DCA circuits 101 and 102, a high power supply potential VDD and a low power supply potential VSS are used. The low power supply potential VSS may be a ground potential.

The DCA circuit 101 includes inverters 110A and 110B. The clock CKI is input to the inverter 110A via an inverter 100. The inverter 110B shares an output with the inverter 110A, and is inputted with the control signal VC1. Here, in the DCA circuit 101, an RC low-pass filter is connected between the inverter 110A and a power supply thereof, in order to suppress the clock CKI from being output with jitter added due to power supply noise. For example, the RC low-pass filter may be connected between the inverter 110A and the high power supply potential VDD, and the RC low-pass filter may be connected between the inverter 110A and the low power supply potential VSS. Note that, a resistor of the RC low-pass filter may be a resistance element, an on-resistor of a field effect transistor, or a series circuit of the resistance element and the on-resistor of the field effect transistor. A resistance value of the resistor of the RC low-pass filter can be set to, for example, several hundred Ω. A capacitance value of a capacitor of the RC low-pass filter can be set to, for example, several pF. The RC low-pass filter can be integrated into the DCA circuit 101.

The inverter 110A includes a P-channel field effect transistor 111 and an N-channel field effect transistor 113. The P-channel field effect transistor 111 and the N-channel field effect transistor 113 are connected in series with each other. The clock CKI is input to a gate of the P-channel field effect transistor 111 and a gate of the N-channel field effect transistor 113 via the inverter 100.

As the RC low-pass filter connected between the inverter 110A and the high power supply potential VDD, a P-channel field effect transistor 115, a resistance element 211, and a capacitor 213 can be used. As the RC low-pass filter connected between the inverter 110A and the low power supply potential VSS, an N-channel field effect transistor 117, a resistance element 212, and the capacitor 213 can be used.

The P-channel field effect transistor 115 and the resistance element 211 are connected in series with each other. The series circuit of the P-channel field effect transistor 115 and the resistance element 211 is connected between the P-channel field effect transistor 111 and the high power supply potential VDD. The N-channel field effect transistor 117 and the resistance element 212 are connected in series with each other. The series circuit of the N-channel field effect transistor 117 and the resistance element 212 is connected between the N-channel field effect transistor 113 and the low power supply potential VSS. The capacitor 213 is connected in parallel with the inverter 110A.

The inverter 110B includes a P-channel field effect transistor 112 and an N-channel field effect transistor 114. The P-channel field effect transistor 112 and the N-channel field effect transistor 114 are connected in series with each other. The control signal VC1 is input to a gate of the P-channel field effect transistor 112 and a gate of the N-channel field effect transistor 114.

A P-channel field effect transistor 116 is connected between the P-channel field effect transistor 112 and the high power supply potential VDD. An N-channel field effect transistor 118 is connected between the N-channel field effect transistor 114 and the low power supply potential VSS.

Bias voltages VB1 and VB3 are input to gates of the P-channel field effect transistors 115 and 116, respectively, and bias voltages VB2 and VB4 are input to gates of the N-channel field effect transistors 117 and 118, respectively. The bias voltages VB1 to VB4 can be set such that each of the P-channel field effect transistor 115 and 116 and the N-channel field effect transistor 117 and 118 operates as a resistor.

The DCA circuit 102 includes inverters 120A and 120B. An output of the DCA circuit 101 is input to the inverter 120A. The inverter 120B shares an output with the inverter 120A, and is inputted with the control signal VC2. Here, in the DCA circuit 102, an RC low-pass filter is connected between the inverter 120A and a power supply thereof, in order to suppress the clock CKI from being output with jitter added due to power supply noise. For example, the RC low-pass filter may be connected between the inverter 120A and the high power supply potential VDD, and the RC low-pass filter may be connected between the inverter 120A and the low power supply potential VSS.

The inverter 120A includes a P-channel field effect transistor 121 and an N-channel field effect transistor 123. The P-channel field effect transistor 121 and the N-channel field effect transistor 123 are connected in series with each other. The output of the DCA circuit 101 is input to a gate of the P-channel field effect transistor 121 and a gate of the N-channel field effect transistor 123.

As the RC low-pass filter connected between the inverter 120A and the high power supply potential VDD, a P-channel field effect transistor 125, a resistance element 221, and a capacitor 223 can be used. As the RC low-pass filter connected between the inverter 120A and the low power supply potential VSS, an N-channel field effect transistor 127, a resistance element 222, and the capacitor 223 can be used.

The P-channel field effect transistor 125 and the resistance element 221 are connected in series with each other. The series circuit of the P-channel field effect transistor 125 and the resistance element 221 is connected between the P-channel field effect transistor 121 and the high power supply potential VDD. The N-channel field effect transistor 127 and the resistance element 222 are connected in series with each other. The series circuit of the N-channel field effect transistor 127 and the resistance element 222 is connected between the N-channel field effect transistor 123 and the low power supply potential VSS. The capacitor 223 is connected in parallel with the inverter 120A.

The inverter 120B includes a P-channel field effect transistor 122 and an N-channel field effect transistor 124. The P-channel field effect transistor 122 and the N-channel field effect transistor 124 are connected in series with each other. The control signal VC2 is input to a gate of the P-channel field effect transistor 122 and a gate of the N-channel field effect transistor 124.

A P-channel field effect transistor 126 is connected between the P-channel field effect transistor 122 and the high power supply potential VDD. An N-channel field effect transistor 128 is connected between the N-channel field effect transistor 124 and the low power supply potential VSS.

The bias voltages VB1 and VB3 are input to gates of the P-channel field effect transistors 125 and 126, respectively, and the bias voltages VB2 and VB4 are input to gates of the N-channel field effect transistors 127 and 128, respectively. The bias voltages VB1 to VB4 can be set such that each of the P-channel field effect transistor 125 and 126 and the N-channel field effect transistor 127 and 128 operates as a resistor.

The differentiation circuit 103 differentiates an output of the inverter 120B to generate differential clocks CKON and CKOP. The differentiation circuit 103 includes inverters 130, 131, 132, 133, 134, 135, 232, and 233 and a transmission gate 231. The output of the inverter 120B is connected to an input of the inverter 130. An output of the inverter 130 is connected to an input of the inverter 131 and an input of the transmission gate 231. The inverters 131 to 133 are connected in series with each other. The transmission gate 231 and the inverters 232 and 233 are connected in series with each other. The inverters 134 and 135 are connected to each other in anti-parallel. The anti-parallel circuit of the inverters 134 and 135 is connected between a connection point of the inverters 132 and 133 and a connection point of the inverters 232 and 233. Here, the anti-parallel circuit of the inverters 134 and 135 can mutually draw potentials of differential outputs, and reduce a deviation of cross points of the differential outputs to balance.

The low-pass filter 104 is connected to a non-inverting input of the amplifier 106, and the low-pass filter 105 is connected to an inverting input of the amplifier 106. At this time, each of the low-pass filters 104 and 105 is AC-coupled to the high power supply potential VDD.

The low-pass filter 104 includes a filter resistor 141 and a filter capacitor 142. The filter resistor 141 is connected in series with the non-inverting input of the amplifier 106. The filter capacitor 142 is in parallel with the non-inverting input of the amplifier 106, and is connected to the high power supply potential VDD.

The low-pass filter 105 includes a filter resistor 151 and a filter capacitor 152. The filter resistor 151 is connected in series with the inverting input of the amplifier 106. The filter capacitor 152 is in parallel with the inverting input of the amplifier 106, and is connected to the high power supply potential VDD.

The amplifier 106 generates the control signals VC1 and VC2 on the basis of the differential clocks CKON and CKOP output from the differentiation circuit 103. As the amplifier 106, a fully differential amplifier can be used.

Here, the clock control device can correct a duty cycle of a clock to ideally 50% to output the clock, by using a negative feedback configuration using the two-stage DCA circuits 101 and 102, the differentiation circuit 103, and the amplifier 106.

Furthermore, by connecting the RC low-pass filter between each of the inverters 110A and 120A and the power supply, it is possible to reduce an error from 50% of the duty cycle of the clock while improving power supply noise resistance of each of the DCA circuits 101 and 102.

Moreover, by connecting the low-pass filters 104 and 105 of the respective differential inputs of the amplifier 106 to the high power supply potential VDD, the PSRRs of the control signals VC1 and VC2 can be brought close to 0 dB, and jitter added to the clock due to power supply noise can be reduced.

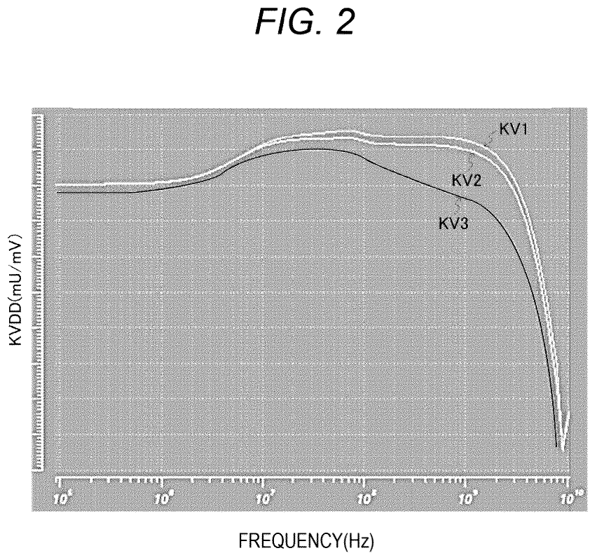

FIG. 2 is a graph illustrating KVDD characteristics of the clock control device according to the first embodiment. Note that a horizontal axis of the figure indicates a frequency (Hz), and a horizontal axis of the figure indicates a jitter value per voltage mV in mUI units. Furthermore, KV1 indicates KVDD characteristics caused when the RC low-pass filter is not connected between each of the inverters 110A and 120A and the power supply thereof and when each of the low-pass filters 104 and 105 of the differential inputs of the amplifier 106 is connected to the low power supply potential VSS. KV2 indicates KVDD characteristics caused when the RC low-pass filter is not connected between each of the inverters 110A and 120A and the power supply thereof and when each of the low-pass filters 104 and 105 of the differential inputs of the amplifier 106 is connected to the high power supply potential VDD. KV3 indicates KVDD characteristics caused when the RC low-pass filter (capacitor: 1.5 PF) is connected between each of the inverters 110A and 120A and the power supply thereof and when each of the low-pass filters 104 and 105 of the differential inputs of the amplifier 106 is connected to the high power supply potential VDD. The KVDD characteristics indicate that jitter with respect to power supply noise is smaller as KVDD is smaller.

In the figure, in the configuration in which the RC low pass filter is connected between each of the inverters 110A and 120A and the power supply thereof, KVDD is smaller than that in the configuration in which the RC low-pass filter is not connected between each of the inverters 110A and 120A and the power supply thereof. In particular, an effect of reducing KVDD has been remarkably exhibited at 100 MHz or more.

In this way, in the first embodiment described above, the RC low-pass filter is connected between each of the inverters 110A and 120A, which are driven on the basis of the clock CKI, and the power supply thereof, and the filter capacitor of each of the low-pass filters 104 and 105 of the respective differential inputs of the amplifier 106 is connected to VDD or VSS or both VDD and VSS. As a result, it is possible to correct the duty cycle of the clock to 50% to output the clock while reducing jitter added to the clock due to power supply noise generated from the high power supply potential VDD and the low power supply potential VSS.

Note that, in the first embodiment described above, an example has been described in which the RC low-pass filter is connected between each of the inverters 110A and 110B and the power supply thereof, and the low-pass filters 104 and 105 of the respective differential inputs of the amplifier 106 are connected to the high power supply potential VDD by AC coupling. On the other hand, a configuration may be used alone in which the RC low-pass filter is connected between each of the inverters 110A and 110B and the power supply thereof, or a configuration may be used alone in which the low-pass filters 104 and 105 of the respective differential inputs of the amplifier 106 are connected to the low power Supply potential VSS by AC coupling.

### 2. Second Embodiment

In the first embodiment described above, the RC low-pass filter is connected between each of the inverters 110A and 120A, which are driven on the basis of the clock CKI, and the power supply thereof. In this second embodiment, a resistor of an RC low-pass filter is connected to both sides of a power supply of an inverter to which a clock is input.

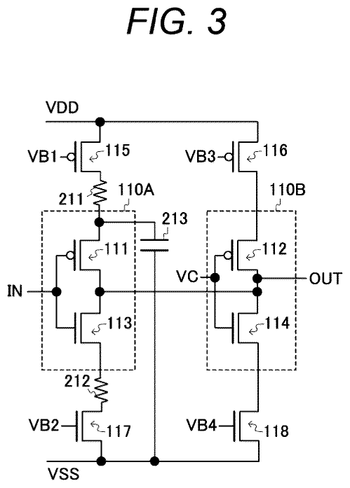

FIG. 3 is a circuit diagram illustrating a first configuration example of a DCA circuit according to the second embodiment.

In the figure, the DCA circuit of the first configuration example of the second embodiment is different from the DCA circuit 101 of the first embodiment in a connection position of a capacitor 213. Other configurations of the DCA circuit of the first configuration example of the second embodiment are similar to those of the DCA circuit 101 of the first embodiment described above.

In this DCA circuit, the capacitor 213 is connected in parallel with a series circuit of an inverter 110A, a resistance element 212, and an N-channel field effect transistor 117. An input signal IN is input to the inverter 110A, and an output signal OUT is output from an inverter 110B. A similar configuration can also be applied to the DCA circuit 102 of the first embodiment described above.

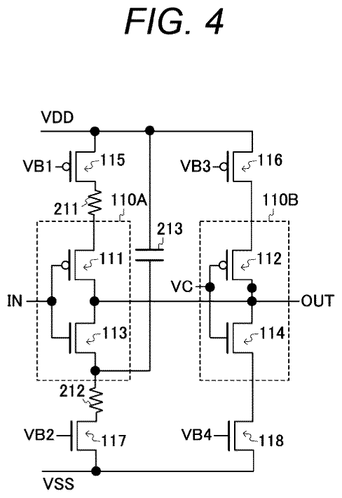

FIG. 4 is a circuit diagram illustrating a second configuration example of the DCA circuit according to the second embodiment.

In the figure, the DCA circuit of the second configuration example of the second embodiment is different from the DCA circuit 101 of the first embodiment in a connection position of the capacitor 213. Other configurations of the DCA circuit of the second configuration example of the second embodiment are similar to those of the DCA circuit 101 of the first embodiment described above.

In this DCA circuit, the capacitor 213 is connected in parallel with a series circuit of the inverter 110A, a resistance element 211, and a P-channel field effect transistor 115. A similar configuration can also be applied to the DCA circuit 102 of the first embodiment described above.

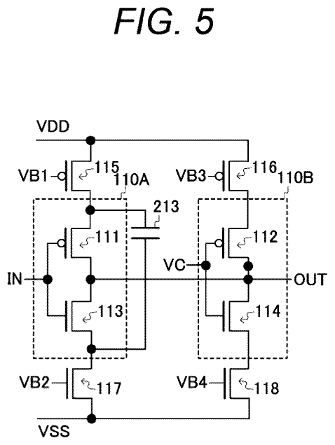

FIG. 5 is a circuit diagram illustrating a third configuration example of the DCA circuit according to the second embodiment.

In the figure, in the DCA circuit of the third configuration example of the second embodiment, the resistance elements 211 and 212 are removed from the resistor of the RC low-pass filter of the first embodiment described above. At this time, an on-resistor of the P-channel field effect transistor 115 and an on-resistor of the N-channel field effect transistor 117 are used as the resistor of the RC low-pass filter connected between the inverter 110A and a power supply thereof. Other configurations of the DCA circuit of the third configuration example of the second embodiment are similar to those of the DCA circuit 101 of the first embodiment described above.

In this DCA circuit, the P-channel field effect transistor 115 is connected between the P-channel field effect transistor 111 and a high power supply potential VDD. The N-channel field effect transistor 117 is connected between the N-channel field effect transistor 113 and a low power supply potential VSS. A similar configuration can also be applied to the DCA circuit 102 of the first embodiment described above.

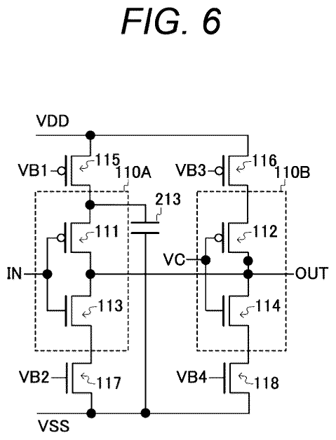

FIG. 6 is a circuit diagram illustrating a fourth configuration example of the DCA circuit according to the second embodiment.

In the figure, the DCA circuit of the fourth configuration example of the second embodiment is different from the DCA circuit of the third configuration example of the second embodiment in a connection position of the capacitor 213. Other configurations of the DCA circuit of the fourth configuration example of the second embodiment are similar to those of the DCA circuit of the third configuration example of the second embodiment. described above.

In this DCA circuit, the capacitor 213 is connected in parallel with a series circuit of the inverter 110A and the N-channel field effect transistor 117. A similar configuration can also be applied to the DCA circuit 102 of the first embodiment described above.

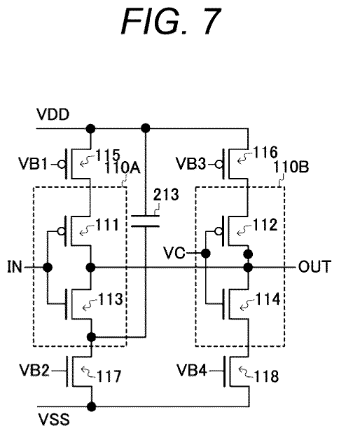

FIG. 7 is a circuit diagram illustrating a fifth configuration example of the DCA circuit according to the second embodiment.

In the figure, the DCA circuit of the fifth configuration example of the second embodiment is different from the DCA circuit of the third configuration example of the second embodiment in a connection position of the capacitor 213. Other configurations of the DCA circuit of the fifth configuration example of the second embodiment are similar to those of the DCA circuit of the third configuration example of the second embodiment described above.

In this DCA circuit, the capacitor 213 is connected in parallel with a series circuit of the inverter 110A and the P-channel field effect transistor 115. A similar configuration can also be applied to the DCA circuit 102 of the first embodiment described above.

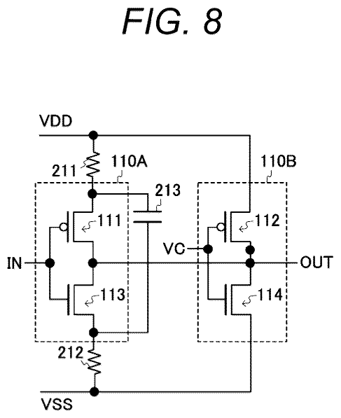

FIG. 8 is a circuit diagram illustrating a sixth configuration example of the DCA circuit according to the second embodiment.

In the figure, in the DCA circuit of the sixth configuration example of the second embodiment, the P-channel field effect transistor 115 and the N-channel field effect transistor 117 are removed from the resistor of the RC low-pass filter of the first embodiment. described above. At this time, the resistance elements 211 and 212 are used as the resistor of the RC low-pass filter connected between the inverter 110A and the power supply thereof. Furthermore, in the DCA circuit of the sixth configuration example of the second embodiment, the P-channel field effect transistor 116 and the N-channel field effect transistor 118 of the first embodiment described above are removed. Other configurations of the DCA circuit of the sixth configuration example of the second embodiment are similar to those of the DCA circuit 101 of the first embodiment described above.

In the DCA circuit, the resistance element 211 is connected between the P-channel field effect transistor 111 and the high power supply potential VDD. The resistance element 212 is connected between the N-channel field effect transistor 113 and the low power supply potential VSS. The inverter 110B is connected between the high power supply potential VDD and the low power supply potential VSS. A similar configuration can also be applied to the DCA circuit 102 of the first embodiment described above.

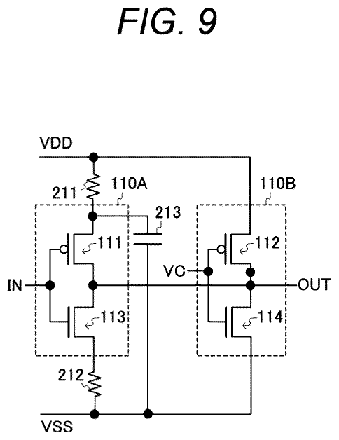

FIG. 9 is a circuit diagram illustrating a seventh configuration example of the DCA circuit according to the second embodiment.

In the figure, the DCA circuit of the seventh configuration example of the second embodiment is different from the DCA circuit of the sixth configuration example of the second embodiment in a connection position of the capacitor 213. Other configurations of the DCA circuit of the seventh configuration example of the second embodiment are similar to those of the DCA circuit of the sixth configuration example of the second embodiment described above.

In this DCA circuit, the capacitor 213 is connected in parallel with a series circuit of the inverter 110A and the resistance element 212. A similar configuration can also be applied to the DCA circuit 102 of the first embodiment described above.

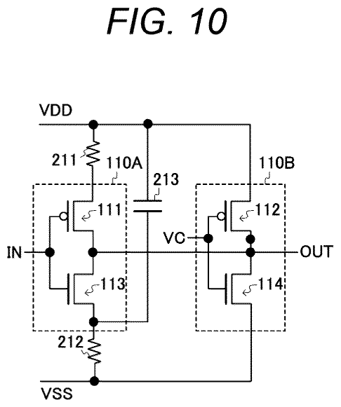

FIG. 10 is a circuit diagram illustrating an eighth configuration example of the DCA circuit according to the second embodiment.

In the figure, the DCA circuit of the eighth configuration example of the second embodiment is different from the DCA circuit of the sixth configuration example of the second embodiment in a connection position of the capacitor 213. Other configurations of the DCA circuit of the eighth configuration example of the second embodiment are similar to those of the DCA circuit of the sixth configuration example of the second embodiment described above.

In this DCA circuit, the capacitor 213 is connected in parallel with a series circuit of the inverter 110A and the resistance element 211. A similar configuration can also be applied to the DCA circuit 102 of the first embodiment described above.

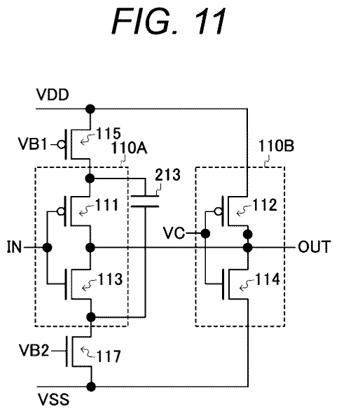

FIG. 11 is a circuit diagram illustrating a ninth configuration example of the DCA circuit according to the second embodiment.

In the figure, the DCA circuit of the ninth configuration example of the second embodiment includes the P-channel field effect transistor 115 and the N-channel field effect transistor 117 instead of the resistance elements 211 and 212 of the sixth configuration example of the second embodiment described above. Other configurations of the DCA circuit of the ninth configuration example of the second embodiment are similar to those of the DCA circuit 101 of the sixth configuration example of the second embodiment.

In this DCA circuit, the P-channel field effect transistor 115 is connected between the P-channel field effect transistor 111 and the high power supply potential VDD. The N-channel field effect transistor 117 is connected between the N-channel field effect transistor 113 and the low power supply potential VSS. A similar configuration can also be applied to the DCA circuit 102 of the first embodiment described above.

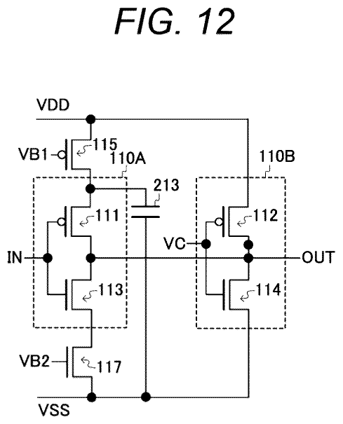

FIG. 12 is a circuit diagram illustrating a tenth configuration example of the DCA circuit according to the second embodiment.

In the figure, the DCA circuit of the tenth configuration example of the second embodiment is different from the DCA circuit of the ninth configuration example of the second embodiment in a connection position of the capacitor 213. Other configurations of the DCA circuit of the tenth configuration example of the second embodiment are similar to those of the DCA circuit of the ninth configuration example of the second embodiment described above.

In this DCA circuit, the capacitor 213 is connected in parallel with a series circuit of the inverter 110A and the N-channel field effect transistor 117. A similar configuration can also be applied to the DCA circuit 102 of the first embodiment described above.

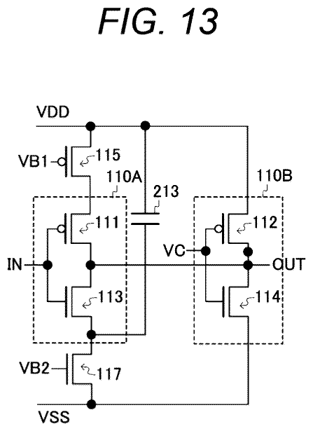

FIG. 13 is a circuit diagram illustrating an eleventh configuration example of the DCA circuit according to the second embodiment.

In the figure, the DCA circuit of the eleventh configuration example of the second embodiment is different from the DCA circuit of the ninth configuration example of the second embodiment in a connection position of the capacitor 213. Other configurations of the DCA circuit of the eleventh configuration example of the second embodiment are similar to those of the DCA circuit of the ninth configuration example of the second embodiment described above.

In this DCA circuit, the capacitor 213 is connected in parallel with a series circuit of the inverter 110A and the P-channel field effect transistor 115. A similar configuration can also be applied to the DCA circuit 102 of the first embodiment described above.

As described above, in the second embodiment described above, the resistor of the RC low-pass filter is connected to both sides of the power supply of the inverter 110A to which the clock is input. As a result, it is possible to correct the duty cycle of the clock to 50% to output the clock while effectively reducing jitter added to the clock due to power supply noise generated from the high power supply potential VDD and the low power supply potential VSS.

### 3. Third Embodiment

In the second embodiment described above, the resistor of the RC low-pass filter connected to the power supply of the inverter 110A to which the clock is input has the same configuration on the high power supply potential VDD side and the low power supply potential VSS side. This third embodiment has a configuration in which a resistor of an RC low-pass filter connected to a power supply of an inverter 110A to which a clock is input is different between a high power supply potential VDD side and a low power supply potential VSS side.

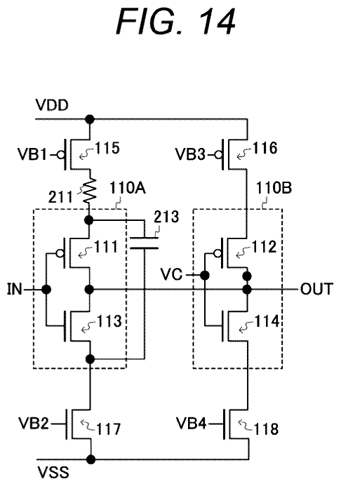

FIG. 14 is a circuit diagram illustrating a first configuration example of a DCA circuit according to the third embodiment.

In the figure, in the DCA circuit of the first configuration example of the third embodiment, the resistance element 212 on the low power supply potential VSS side of the inverter 110A of the first embodiment described above is removed. At this time, on the low power supply potential VSS side of the inverter 110A, an on-resistor of an N-channel field effect transistor 117 is used as the resistor of the RC low-pass filter connected between the inverter 110A and the power supply thereof. Other configurations of the DCA circuit of the first configuration example of the third embodiment are similar to those of the DCA circuit 101 of the first embodiment described above.

In this DCA circuit, the N-channel field effect transistor 117 is connected between the N-channel field effect transistor 113 and the low power supply potential VSS. A similar configuration can also be applied to the DCA circuit 102 of the first embodiment described above.

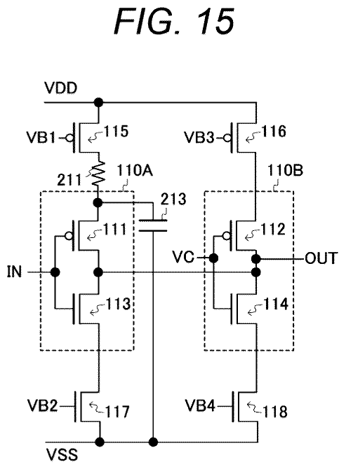

FIG. 15 is a circuit diagram illustrating a second configuration example of the DCA circuit according to the third embodiment.

In the figure, the DCA circuit of the second configuration example of the third embodiment is different from the DCA circuit of the first configuration example of the third embodiment in a connection position of a capacitor 213. Other configurations of the DCA circuit of the second configuration example of the third embodiment are similar to those of the DCA circuit of the first configuration example of the third embodiment described above.

In this DCA circuit, the capacitor 213 is connected in parallel with a series circuit of the inverter 110A and the N-channel field effect transistor 117. A similar configuration can also be applied to the DCA circuit 102 of the first embodiment described above.

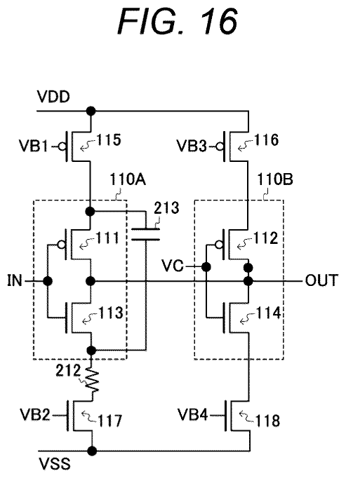

FIG. 16 is a circuit diagram illustrating a third configuration example of the DCA circuit according to the third embodiment.

In the figure, in the DCA circuit of the third configuration example of the third embodiment, the resistance element 211 on the high power supply potential VDD side of the inverter 110A of the first embodiment described above is removed. At this time, on the high power supply potential VDD side of the inverter 110A, an on-resistor of a P-channel field effect transistor 115 is used as the resistor of the RC low-pass filter connected between the inverter 110A and the power supply thereof. Other configurations of the DCA circuit of the third configuration example of the third embodiment are similar to those of the DCA circuit 101 of the first embodiment described above.

In this DCA circuit, the P-channel field effect transistor 115 is connected between a P-channel field effect transistor 111 and the high power supply potential VDD. A similar configuration can also be applied to the DCA circuit 102 of the first embodiment described above.

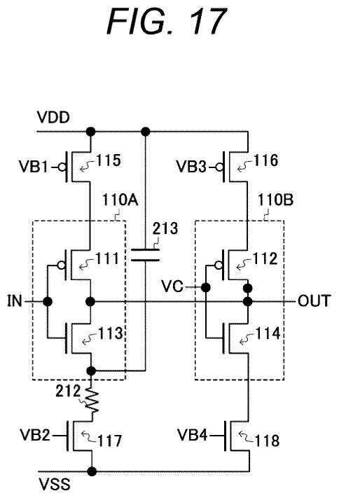

FIG. 17 is a circuit diagram illustrating a fourth configuration example of the DCA circuit according to the third embodiment.

In the figure, the DCA circuit of the fourth configuration example of the third embodiment is different from the DCA circuit of the third configuration example of the third embodiment in a connection position of the capacitor 213. Other configurations of the DCA circuit of the fourth configuration example of the third embodiment are similar to those of the DCA circuit of the third configuration example of the third embodiment described above.

In this DCA circuit, the capacitor 213 is connected in parallel with a series circuit of the inverter 110A and the P-channel field effect transistor 115. A similar configuration can also be applied to the DCA circuit 102 of the first embodiment described above.

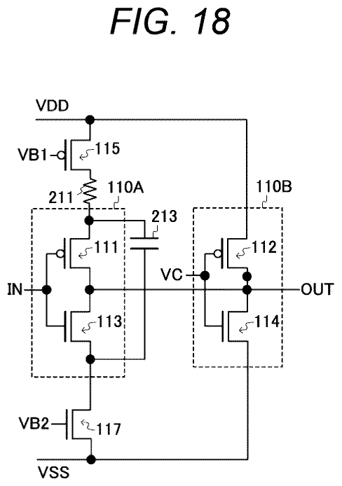

FIG. 18 is a circuit diagram illustrating a fifth configuration example of the DCA circuit according to the third embodiment.

In the figure, in the DCA circuit of the fifth configuration example of the third embodiment, the P-channel field effect transistor 116 and the N-channel field effect transistor 118 are removed from the DCA circuit of the first configuration example of the third embodiment described above. Other configurations of the DCA circuit of the fifth configuration example of the third embodiment are similar to those of the DCA circuit of the first configuration example of the third embodiment described above.

In this DCA circuit, an inverter 110B is connected between the high power supply potential VDD and the low power supply potential VSS. A similar configuration can also be applied to the DCA circuit 102 of the first embodiment described above.

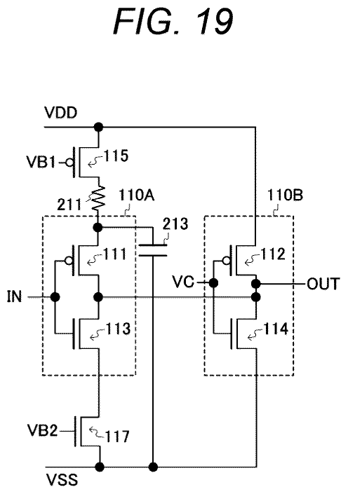

FIG. 19 is a circuit diagram illustrating a sixth configuration example of the DCA circuit according to the third embodiment.

In the figure, in the DCA circuit of the sixth configuration example of the third embodiment, the P-channel field effect transistor 116 and the N-channel field effect transistor 118 are removed from the DCA circuit of the second configuration example of the third embodiment described above. Other configurations of the DCA circuit of the sixth configuration example of the third embodiment are similar to those of the DCA circuit of the second configuration example of the third embodiment described above.

In this DCA circuit, the inverter 110B is connected between the high power supply potential VDD and the low power supply potential VSS. A similar configuration can also be applied to the DCA circuit 102 of the first embodiment described above.

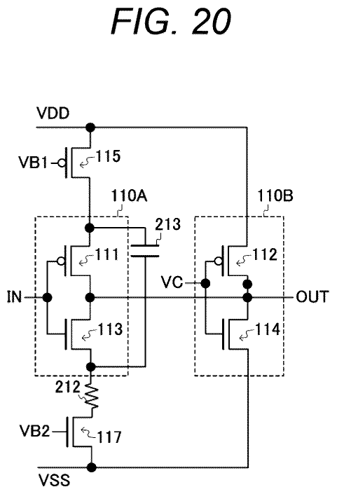

FIG. 20 is a circuit diagram illustrating a seventh configuration example of the DCA circuit according to the third embodiment.

In the figure, in the DCA circuit of the seventh configuration example of the third embodiment, the P-channel field effect transistor 116 and the N-channel field effect transistor 118 are removed from the DCA circuit of the third configuration example of the third embodiment described above. Other configurations of the DCA circuit of the seventh configuration example of the third embodiment are similar to those of the DCA circuit of the third configuration example of the third embodiment described above.

In this DCA circuit, the inverter 110B is connected between the high power supply potential VDD and the low power supply potential VSS. A similar configuration can also be applied to the DCA circuit 102 of the first embodiment described above.

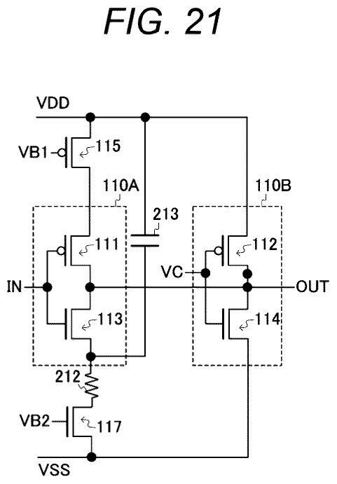

FIG. 21 is a circuit diagram illustrating an eighth configuration example of the DCA circuit according to the third embodiment.

In the figure, in the DCA circuit of the eighth configuration example of the third embodiment, the P-channel field effect transistor 116 and the N-channel field effect transistor 118 are removed from the DCA circuit of the fourth configuration example of the third embodiment described above. Other configurations of the DCA circuit of the eighth configuration example of the third embodiment are similar to those of the DCA circuit of the fourth configuration example of the third embodiment described above.

In this DCA circuit, the inverter 110B is connected between the high power supply potential VDD and the low power supply potential VSS. A similar configuration can also be applied to the DCA circuit 102 of the first embodiment described above.

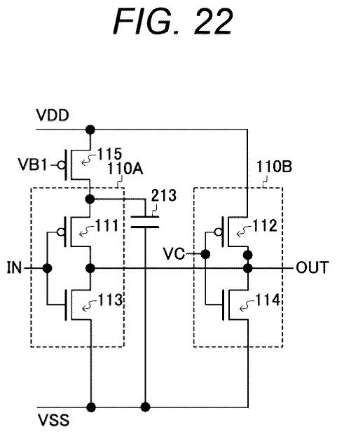

FIG. 22 is a circuit diagram illustrating a ninth configuration example of the DCA circuit according to the third embodiment.

In the figure, in the DCA circuit of the ninth configuration example of the third embodiment, the N-channel field effect transistor 117 is removed from the DCA circuit of the tenth configuration example of the second embodiment described above. Other configurations of the DCA circuit of the ninth configuration example of the third embodiment are similar to those of the DCA circuit of the tenth configuration example of the second embodiment described above.

In this DCA circuit, the capacitor 213 is connected in parallel with the inverter 110A. A similar configuration can also be applied to the DCA circuit 102 of the first embodiment described above.

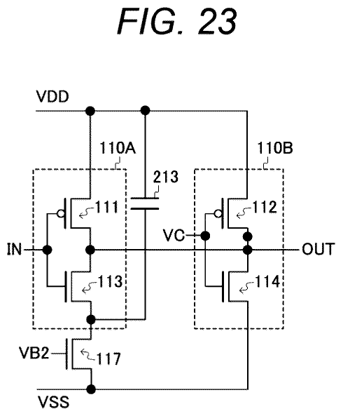

FIG. 23 is a circuit diagram illustrating a tenth configuration example of the DCA circuit according to the third embodiment.

In the figure, in the DCA circuit of the tenth configuration example of the third embodiment, the P-channel field effect transistor 115 is removed from the DCA circuit of the eleventh configuration example of the second embodiment described above. Other configurations of the DCA circuit of the tenth configuration example of the third embodiment are similar to those of the DCA circuit of the eleventh configuration example of the second embodiment described above.

In this DCA circuit, the capacitor 213 is connected in parallel with the inverter 110A. A similar configuration can also be applied to the DCA circuit 102 of the first embodiment described above.

In this way, the third embodiment described above has a configuration in which the resistor of the RC low-pass filter connected to the power supply of the inverter 110A to which the clock is input is different between the high power supply potential VDD side and the low power supply potential VSS side. As a result, it is possible to correct the duty cycle of the clock to 50% to output the clock while effectively reducing jitter added to the clock due to power supply noise.

### 4. Fourth Embodiment

In the first embodiment described above, the capacitors 142 and 152 of the respective low-pass filters 104 and 105 connected to the differential inputs of the amplifier 106 are connected to the high power supply potential VDD. In this fourth embodiment, capacitors of respective low-pass filters connected to differential inputs of an amplifier 106 are connected to a low power supply potential VSS.

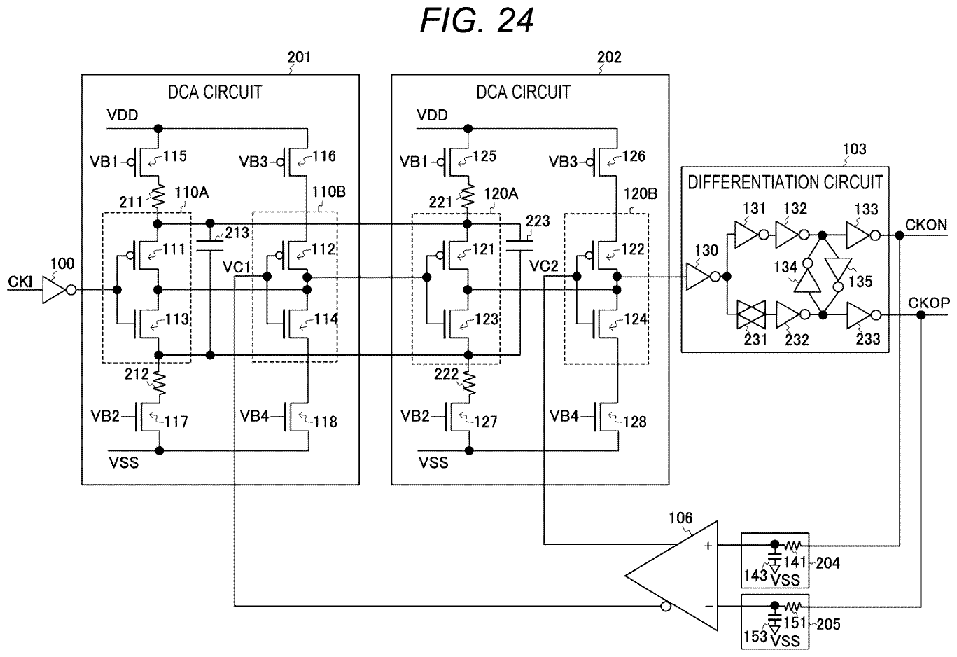

FIG. 24 is a circuit diagram illustrating a configuration example of a clock control device according to the fourth embodiment.

In the figure, the clock control device includes DCA circuits 201 and 202 and low-pass filters 204 and 205 instead of the DCA circuits 101 and 102 and the low-pass filters 104 and 105 of the first embodiment described above. Other configurations of the clock control device of the fourth embodiment are similar to those of the clock control device of the first embodiment described above.

In the DCA circuits 201 and 202, capacitors 213 and 223 are connected in parallel with each other. In this configuration, any one of the capacitors 213 and 223 may be removed. Other configurations of the DCA circuits 201 and 202 are similar to those of the DCA circuits 101 and 102 of the first embodiment described above.

The low-pass filter 204 is connected to a non-inverting input of the amplifier 106, and the low-pass filter 205 is connected to an inverting input of the amplifier 106. At this time, each of the low-pass filters 204 and 205 is AC-coupled to the low power supply potential VSS.

The low-pass filter 204 includes a filter resistor 141 and a filter capacitor 143. The filter capacitor 143 is in parallel with the non-inverting input of the amplifier 106, and is connected to the low power supply potential VSS.

The low-pass filter 205 includes a filter resistor 151 and a filter capacitor 153. The filter capacitor 153 is in parallel with the inverting input of the amplifier 106, and is connected to the low power supply potential VSS.

As described above, in the fourth embodiment described above, the capacitors 143 and 153 of the respective low-pass filters 204 and 205 connected to the differential inputs of the amplifier 106 are connected to the low power supply potential VSS. As a result, it is possible to correct the duty cycle of the clock to 50% to output the clock while reducing jitter added to the clock due to power supply noise.

### 5. Fifth Embodiment

In the first embodiment described above, the capacitors 142 and 152 of the respective low-pass filters 104 and 105 connected to the differential inputs of the amplifier 106 are connected to the high power supply potential VDD. In this fifth embodiment, capacitors of low-pass filters connected to differential inputs of an amplifier 106 are connected to a high power supply potential VDD and a low power supply potential VSS.

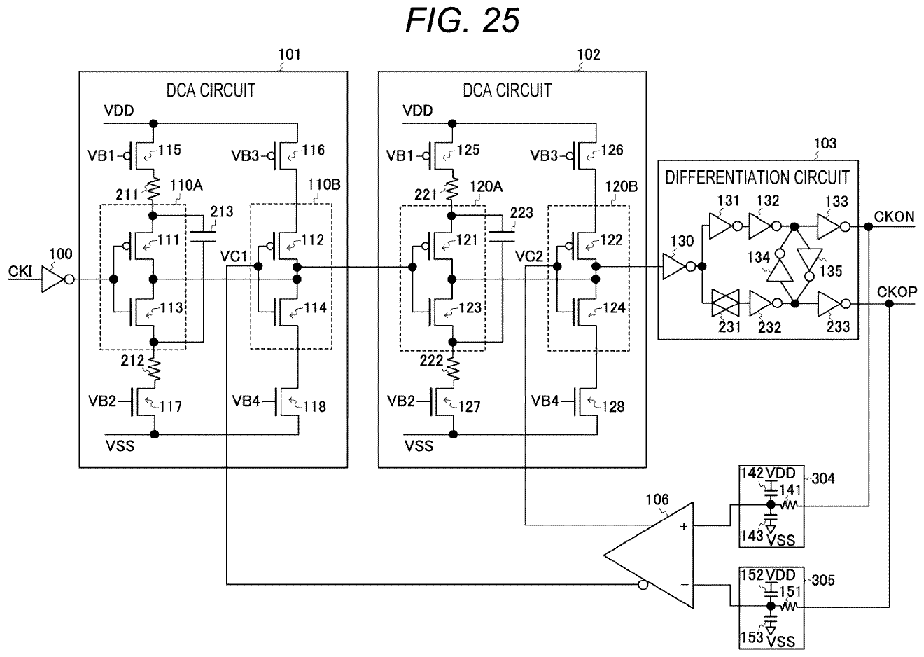

FIG. 25 is a circuit diagram illustrating a configuration example of a clock control device according to the fifth embodiment.

In the figure, the clock control device includes low-pass filters 304 and 305 instead of the low-pass filters 104 and 105 of the first embodiment described above. Other configurations of the clock control device of the fifth embodiment are similar to those of the clock control device of the first embodiment described above.

The low-pass filter 304 is connected to a non-inverting input of the amplifier 106, and the low-pass filter 305 is connected to an inverting input of the amplifier 106. At this time, each of the low-pass filters 304 and 305 is AC-coupled to the high power supply potential VDD and the low power supply potential VSS.

The low-pass filter 304 includes a filter resistor 141 and filter capacitors 142 and 143. The low-pass filter 305 includes a filter resistor 151 and filter capacitors 152 and 153.

As described above, in the fifth embodiment described above, the capacitors 142 and 152 of the respective low-pass filters 304 and 305 connected to the differential inputs of the amplifier 106 are connected to the high power supply potential VDD, and the capacitors 143 and 153 are connected to the low power supply potential VSS. As a result, it is possible to correct. the duty cycle of the clock to 50% to output the clock while reducing jitter added to the clock due to power supply noise.

### 6. Sixth Embodiment

In the fifth embodiment described above, the capacitors of the low-pass filters connected to the differential inputs of the amplifier 106 are connected to the high power supply potential VDD and the low power supply potential VSS. In this sixth embodiment, a local low-pass filter is connected to gate inputs of P-channel field effect transistors 112 and 122 and N-channel field effect transistors 114 and 124 to which respective control signals VC1 and VC2 are input.

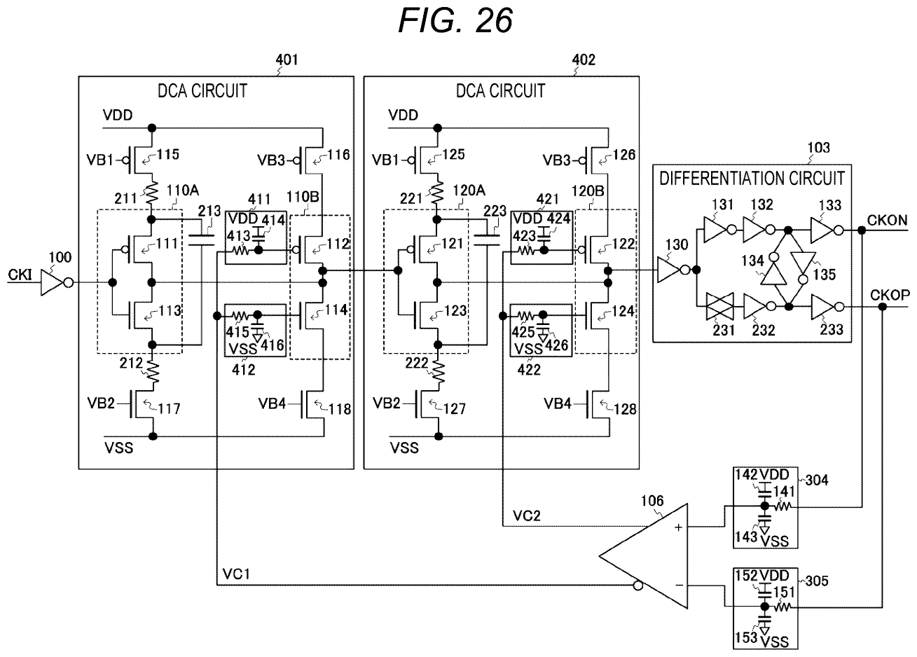

FIG. 26 is a circuit diagram illustrating a configuration example of a clock control device according to the sixth embodiment.

In the figure, the clock control device includes DCA circuits 401 and 402 instead of the DCA circuits 101 and 102 of the fifth embodiment described above. Other configurations of the clock control device of the sixth embodiment are similar to those of the clock control device of the fifth embodiment described above.

In the DCA circuits 401 and 402, local low-pass filters 411, 412, 421, and 422 are added to the DCA circuits 101 and 102 of the fifth embodiment described above. Other configurations of the DCA circuits 401 and 402 of the sixth embodiment are similar to those of the DCA circuits 101 and 102 of the fifth embodiment described above.

The local low-pass filter 411 is connected to a gate of the P-channel field effect transistor 112, and the local low-pass filter 412 is connected to a gate of the N-channel field effect transistor 114. At this time, the control signal VC1 is input to the gate of the P-channel field effect transistor 112 via the local low-pass filter 411, and is input to the gate of the N-channel field effect transistor 114 via the local low-pass filter 412.

The local low-pass filter 411 includes a filter resistor 413 and a filter capacitor 414. The filter resistor 413 is in series with the gate input of the P-channel field effect transistor 112. The filter capacitor 414 is in parallel with the gate input of the P-channel field effect transistor 112, and is connected to a high power supply potential VDD.

The local low-pass filter 412 includes a filter resistor 415 and a filter capacitor 416. The filter resistor 415 is in series with the gate input of the N-channel field effect transistor 114. The filter capacitor 416 is in parallel with the gate input of the N-channel field effect transistor 114, and is connected to a low power supply potential VSS.

The local low-pass filter 421 is connected to a gate of the P-channel field effect transistor 122, and the local low-pass filter 422 is connected to a gate of the N-channel field effect transistor 124. At this time, the control signal VC2 is input to the gate of the P-channel field effect transistor 122 via the local low-pass filter 421, and is input to the gate of the N-channel field effect transistor 124 via the local low-pass filter 422.

The local low-pass filter 421 includes a filter resistor 423 and a filter capacitor 424. The filter resistor 423 is in series with the gate input of the P-channel field effect transistor 122. The filter capacitor 424 is in parallel with the gate input of the P-channel field effect transistor 122, and is connected to the high power supply potential VDD.

The local low-pass filter 422 includes a filter resistor 425 and a filter capacitor 426. The filter resistor 425 is in series with the gate input of the N-channel field effect transistor 124. The filter capacitor 426 is in parallel with the gate input of the N-channel field effect transistor 124, and is connected to the low power supply potential VSS.

As described above, in the sixth embodiment described above, the local low-pass filters 411, 412, 421, and 422 are connected to the gate inputs of the respective field effect transistors to which the respective control signals VC1 and VC2 are input. As a result, jitter added to the clock due to power supply noise can be reduced on the basis of a low-pass filter effect of the gate inputs of respective field effect transistors to which the respective control signals VC1 and VC2 are input.

### 7. Seventh Embodiment

In the sixth embodiment described above, the local low-pass filters are connected to the gate input of the P-channel field effect transistor and the gate input of the N-channel field effect transistor to which the respective control signals VC1 and VC2 are input. In this seventh embodiment, a local low-pass filter is connected to gate inputs of N-channel field effect transistors to which respective control signals VC1 and VC2 are input.

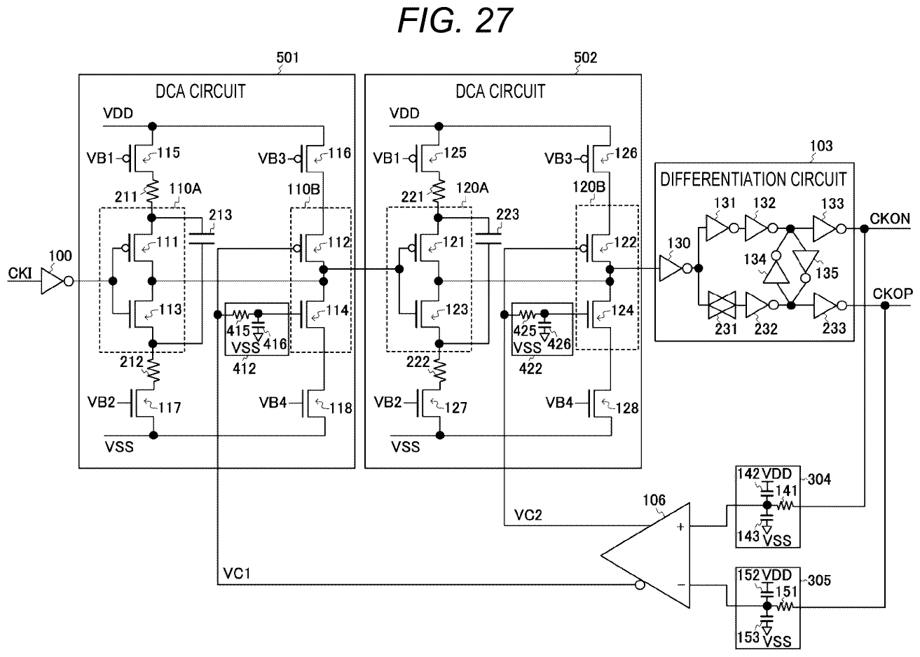

FIG. 27 is a circuit diagram illustrating a configuration example of a clock control device according to the seventh embodiment.

In the figure, the clock control device includes DCA circuits 501 and 502 instead of the DCA circuits 101 and 102 of the fifth embodiment described above. Other configurations of the clock control device of the seventh embodiment are similar to those of the clock control device of the fifth embodiment described above.

In the DCA circuits 501 and 502, local low-pass filters 412 and 422 are added to the DCA circuits 101 and 102 of the fifth embodiment described above. Other configurations of the DCA circuits 501 and 502 of the seventh embodiment are similar to those of the DCA circuits 101 and 102 of the fifth embodiment described above.

As described above, in the seventh embodiment described above, the local low-pass filters 412 and 422 are connected to gate inputs of respective N-channel field effect transistors 114 and 124 to which the respective control signals VC1 and VC2 are input. As a result, jitter added to the clock due to power supply noise can be reduced on the basis of a low-pass filter effect of the gate inputs of the respective N-channel field effect transistors 114 and 124 to which the respective control signals VC1 and VC2 are input.

### 8. Eighth Embodiment

In the sixth embodiment described above, the local low-pass filters are connected to the gate input of the P-channel field effect transistor and the gate input of the N-channel field effect transistor to which the respective control signals VC1 and VC2 are input. In this eighth embodiment, a local low-pass filter is connected to gate inputs of P-channel field effect transistors to which respective control signals VC1 and VC2 are input.

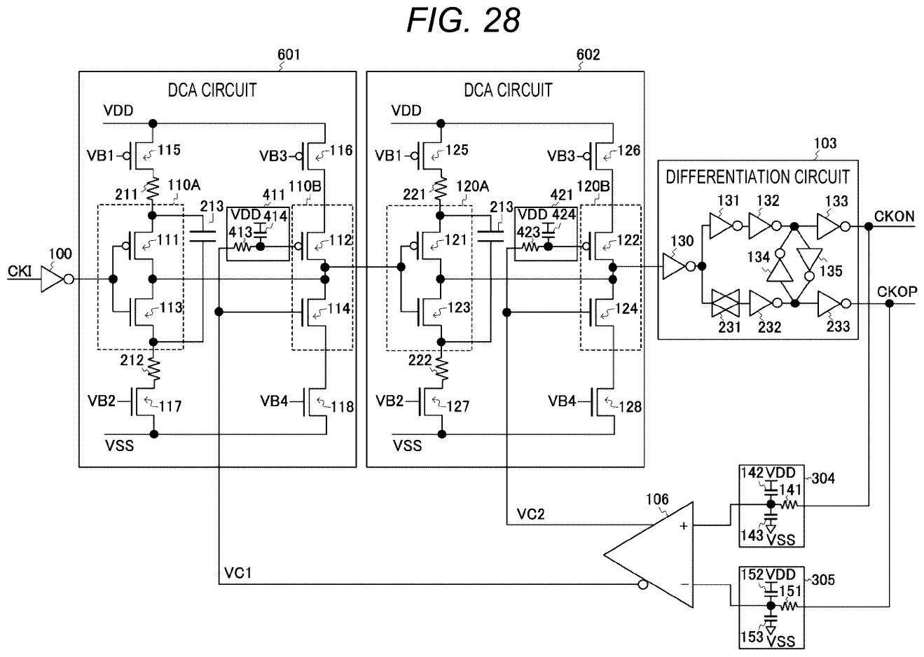

FIG. 28 is a circuit diagram illustrating a configuration example of a clock control device according to the eighth embodiment.

In the figure, the clock control device includes DCA circuits 601 and 602 instead of the DCA circuits 301 and 302 of the fifth embodiment described above. Other configurations of the clock control device of the eighth embodiment are similar to those of the clock control device of the fifth embodiment described above.

In the DCA circuits 601 and 602, local low-pass filters 411 and 421 are added to the DCA circuits 101 and 102 of the first embodiment described above. Other configurations of the DCA circuits 601 and 602 of the eighth embodiment are similar to those of the DCA circuits 101 and 102 of the first embodiment described above.

As described above, in the eighth embodiment described above, the local low-pass filters 411 and 421 are connected to gate inputs of respective P-channel field effect transistors 112 and 122 to which the respective control signals VC1 and VC2 are input. As a result, jitter added to the clock due to power supply noise can be reduced on the basis of a low-pass filter effect of the gate inputs of the respective P-channel field effect transistors 112 and 122 to which the respective control signals VC1 and VC2 are input.

### 9. Ninth Embodiment

In the seventh embodiment described above, the local low-pass filters 412 and 422 are connected to the gate inputs of the respective N-channel field effect transistors 114 and 124, and the low-pass filters 304 and 305 connected to the high power supply potential VDD and the low power supply potential VSS are provided. In this ninth embodiment, local low-pass filters 412 and 422 are connected to gate inputs of respective N-channel field effect transistors 114 and 124, and low-pass filters 104 and 105 connected to a high power supply potential VDD are provided.

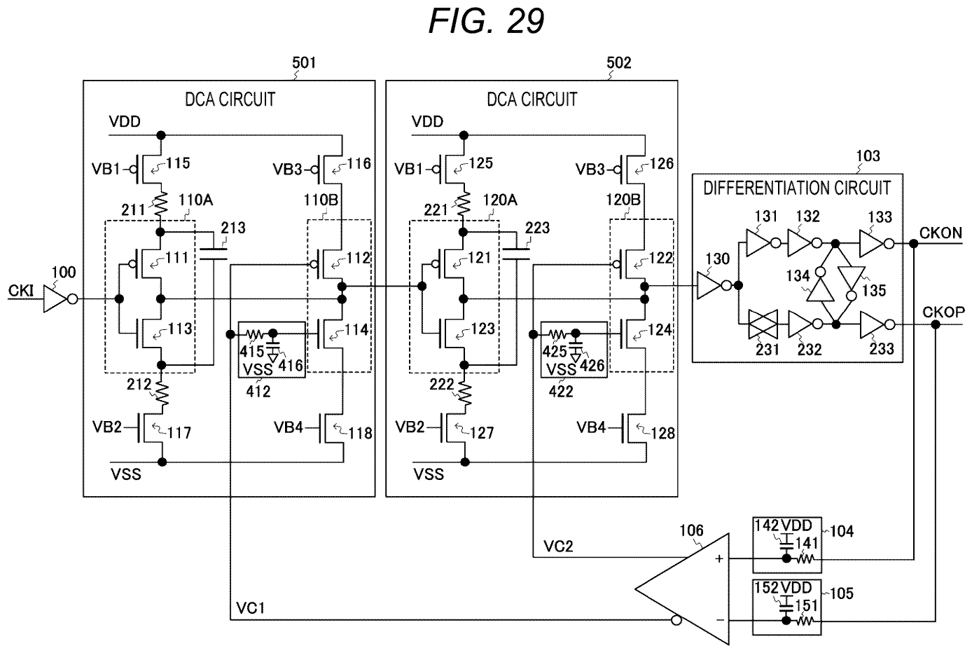

FIG. 29 is a circuit diagram illustrating a configuration example of a clock control device according to the ninth embodiment.

In the figure, the clock control device includes the low-pass filters 104 and 105 instead of the low-pass filters 304 and 305 of the seventh embodiment described above. Other configurations of the clock control device of the ninth embodiment are similar to those of the clock control device of the seventh embodiment described above.

In this way, in the ninth embodiment described above, the local low-pass filters 412 and 422 are connected to the gate inputs of the respective N-channel field effect transistors 114 and 124, and the low-pass filters 104 and 105 connected to the high power supply potential VDD are provided. As a result, it is possible to correct the duty cycle of the clock to 50% to output the clock while reducing jitter added to the clock due to power supply noise.

### 10. Tenth Embodiment

In the eighth embodiment described above, the local low-pass filters 411 and 421 are connected to the gate inputs of the respective P-channel field effect transistors 112 and 122, and the low-pass filters 304 and 305 connected to the high power supply potential VDD and the low power supply potential VSS are provided. In this tenth embodiment, local low-pass filters 411 and 421 are connected to gate inputs of respective P-channel field effect transistors 112 and 122, and low-pass filters 204 and 205 connected to a low power supply potential VSS are provided.

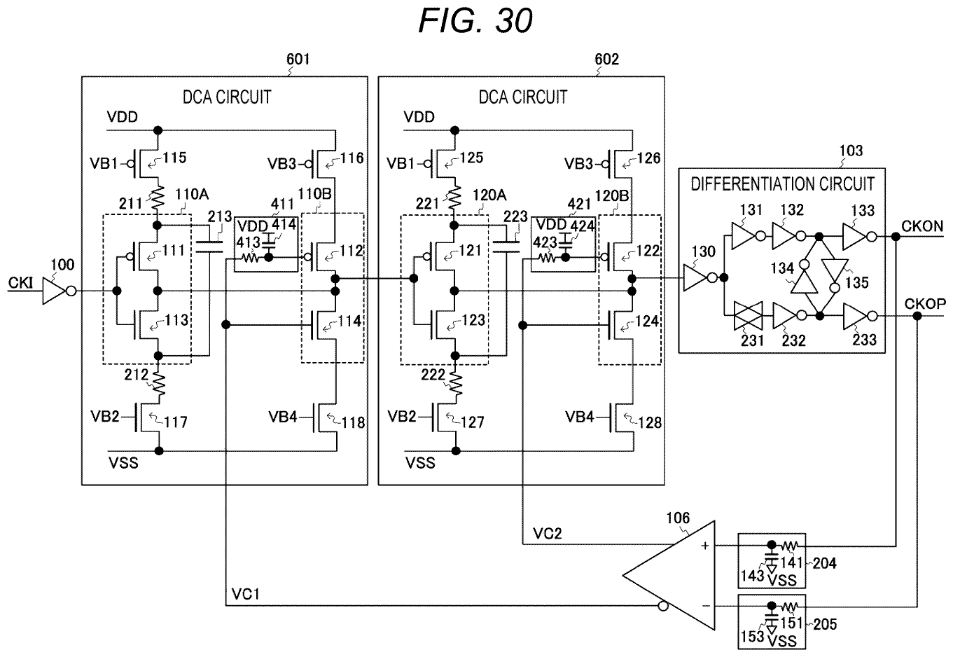

FIG. 30 is a circuit diagram illustrating a configuration example of a clock control device according to the tenth embodiment.

In the figure, the clock control device includes the low-pass filters 204 and 205 instead of the low-pass filters 304 and 305 of the eighth embodiment described above. Other configurations of the clock control device of the tenth embodiment are similar to those of the clock control device of the eighth embodiment described above.

In this way, in the tenth embodiment described above, the local low-pass filters 412 and 422 are connected to the gate inputs of respective N-channel field effect transistors 114 and 124, and the low-pass filters 204 and 205 connected to the low power supply potential SSD are provided. As a result, it is possible to correct the duty cycle of the clock to 50% to output the clock while reducing jitter added to the clock due to power supply noise.

### 11. Eleventh Embodiment

In the first embodiment described above, the clock control device has the negative feedback configuration using the two-stage DCA circuits 101 and 102, the differentiation circuit 103, and the amplifier 106. In this eleventh embodiment, a clock control device has a negative feedback configuration using a one-stage DCA circuit 101, a differentiation circuit 103, and an amplifier.

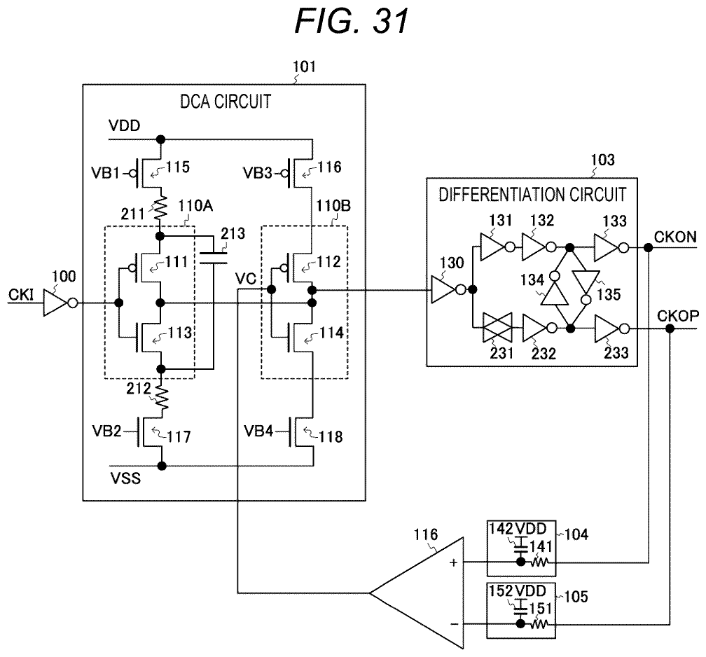

FIG. 31 is a circuit diagram illustrating a configuration example of a clock control device according to the eleventh embodiment.

In the figure, in the clock control device, the DCA circuit 102 is removed from the clock control device of the first embodiment described above. Furthermore, the clock control device includes an amplifier 116 instead of the amplifier 106 of the first embodiment described above. Other configurations of the clock control device of the eleventh embodiment are similar to those of the clock control device of the first embodiment described above.

The differentiation circuit 103 is connected at a subsequent stage of the DCA circuit 101. At this time, an output of an inverter 110B is connected to the input of an inverter 130.

The amplifier 116 generates a control signal VC on the basis of differential clocks CKON and CKOP output from the differentiation circuit 103. The control signal VC is input to the inverter 110B. As the amplifier 106, a differential input single-ended output amplifier can be used.

Here, the clock control device can correct a duty cycle of a clock to ideally 50% to output the clock by using a negative feedback configuration using the one-stage DCA circuit 101, the differentiation circuit 103, and the amplifier 116.

In this way, in the eleventh embodiment described above, an RC low-pass filter is connected between the inverter 110A, which is driven on the basis of a clock CKI, and the power supply thereof, and a filter capacitor of each of the low-pass filters 104 and 105 of the respective differential inputs of the amplifier 116 is connected to VDD, VSS, or VDD and VSS. As a result, it is possible to correct the duty cycle of the clock to 50% to output the clock while reducing jitter added to the clock due to power supply noise generated from the high power supply potential VDD and the low power supply potential VSS.

### 12. Twelfth Embodiment

In the first embodiment described above, the DCA circuits 101 and 102 are provided in which the RC low-pass filter is connected between each of the inverters 110A and 120A, which are driven on the basis of the clock CKI, and the power supply thereof. In this twelfth embodiment, a duty cycle correction (DCC) circuit provided with DCA circuits 101 and 102 is applied to a communication interface.

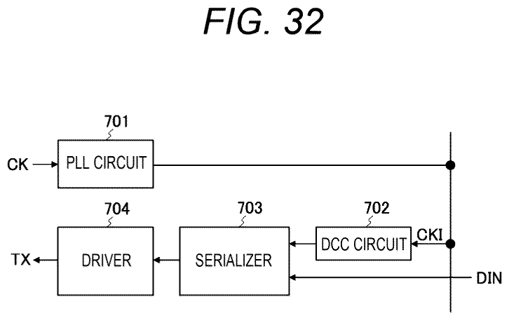

FIG. 32 is a block diagram illustrating a configuration example of a communication interface according to the twelfth embodiment.

In the figure, the communication interface includes a phase locked loop (PLL) circuit 701, a DCC circuit 702, a serializer 703, and a driver 704.

The PLL circuit 701 generates a clock CKI whose frequency multiplication and phase are synchronized on the basis of an input signal CK, and outputs the clock CKI to the DCC circuit 702. The DCC circuit 702 corrects a duty cycle of the clock CKI to 50%, to output the clock CKI to the serializer 703. For the DCC circuit 702, any of the clock control devices of the first to eleventh embodiments described above may be used. The serializer 703 serializes input data DIN in accordance with the clock CKI, and outputs the input data DIN to the driver 704. The driver 704 outputs transmission data TX on the basis of the serial data output from the serializer 703.

Note that this communication interface can be applied to a physical layer (PHY) that is used for communication. This communication interface can be used for a wireless local area network (LAN), Ethernet, a universal serial bus (USB), a serial advanced technology attachment (SATA), and the like.

As described above, in the twelfth embodiment described above, the DCC circuit 702 provided with the DCA circuits 101 and 102 is applied to the communication interface. As a result, the DCC circuit 702 can correct the duty cycle of the clock CKI to 50% to output the clock CKI to the serializer 703 while reducing jitter added to the clock CKI due to power supply noise.

### 13. Thirteenth Embodiment

In the first embodiment described above, the RC low-pass filter is connected between each of the inverters 110A and 120A, which are driven on the basis of the clock CKI, and the power supply thereof. In this thirteenth embodiment, a plurality of RC low-pass filters is connected to a power supply of an inverter 110A to which a clock is input.

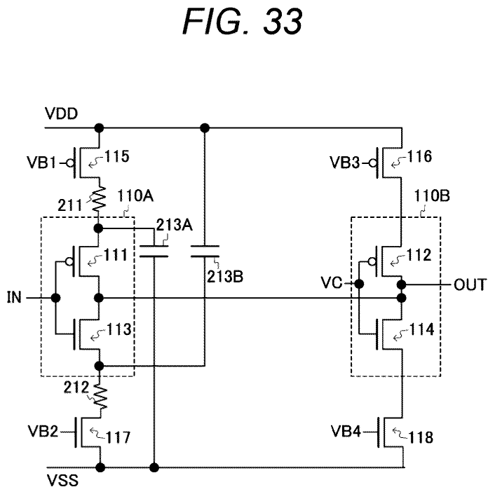

FIG. 33 is a circuit diagram illustrating a first configuration example of a DCA circuit according to the thirteenth embodiment.

In the figure, the DCA circuit of the first configuration example of the thirteenth embodiment includes capacitors 213A and 213B instead of the capacitor 213 of the DCA circuit of FIG. 3 described above. Other configurations of the DCA circuit of the first configuration example of the thirteenth embodiment are similar to those of the DCA circuit of FIG. 3 described above.

The capacitor 213A is connected in parallel with a series circuit of the inverter 110A, a resistance element 212, and an N-channel field effect transistor 117. The capacitor 213B is connected in parallel with a series circuit of the inverter 110A, a resistance element 211, and a P-channel field effect transistor 115.

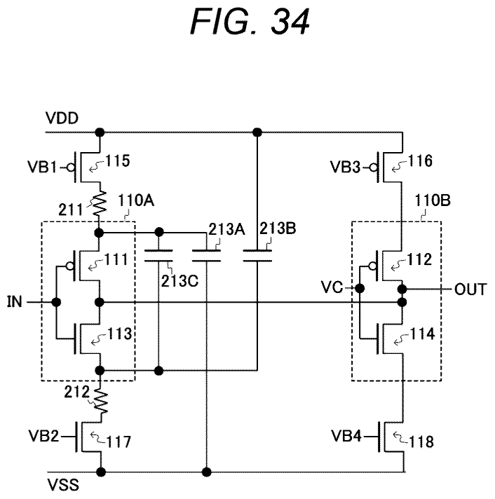

FIG. 34 is a circuit diagram illustrating a second configuration example of the DCA circuit according to the thirteenth embodiment.

In the figure, in the DCA circuit of the second configuration example of the thirteenth embodiment, a capacitor 213C is added to the DCA circuit of FIG. 33 described above. The capacitor 213C is connected in parallel with the inverter 110A. Other configurations of the DCA circuit of the second configuration example of the thirteenth embodiment are similar to those of the DCA circuit of FIG. 33 described above.

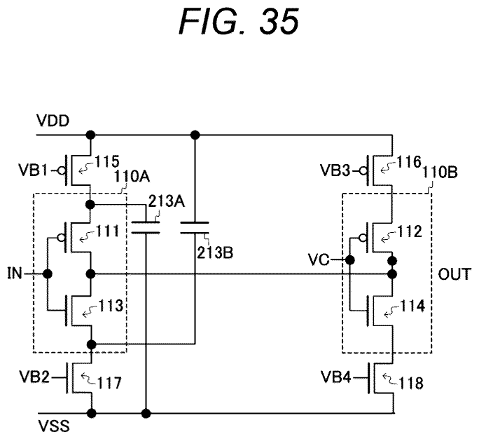

FIG. 35 is a circuit diagram illustrating a third configuration example of the DCA circuit according to the thirteenth embodiment.

In the figure, the DCA circuit of the third configuration example of the thirteenth embodiment includes the capacitors 213A and 213B instead of the capacitor 213 of the DCA circuit of FIG. 6 described above. Other configurations of the DCA circuit of the thirteenth configuration example of the thirteenth embodiment are similar to those of the DCA circuit of FIG. 6 described above.

The capacitor 213A is connected in parallel with a series circuit of the inverter 110A and the N-channel field effect transistor 117. The capacitor 213B is connected in parallel with a series circuit of the inverter 110A and the P-channel field effect transistor 115.

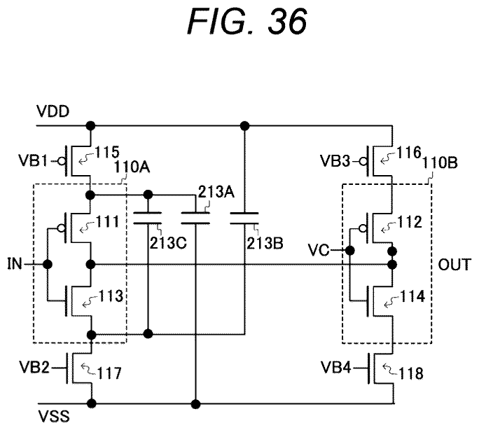

FIG. 36 is a circuit diagram illustrating a fourth configuration example of the DCA circuit according to the thirteenth embodiment.

In the figure, in the DCA circuit of the fourth configuration example of the thirteenth embodiment, the capacitor 213C is added to the DCA circuit of FIG. 35 described above. The capacitor 2130 is connected in parallel with the inverter 110A. Other configurations of the DCA circuit of the fourth configuration example of the thirteenth embodiment are similar to those of the DCA circuit of FIG. 35 described above.

As described above, in the thirteenth embodiment described above, a plurality of RC low-pass filters is provided, which are individually connected to a low power supply potential VSS side and a high power supply potential VDD side of the inverter 110A to which the clock is input. As a result, it is possible to correct the duty cycle of the clock to 50% to output the clock while effectively reducing jitter added to the clock due to power supply noise generated from the high power supply potential VDD and the low power supply potential VSS.

Note that the embodiments described above indicate examples for embodying the present technology, and the individual matters in the embodiments and the individual matters specifying the invention in the claims have correspondence relationships. Similarly, the individual matters specifying the invention in the claims and the individual matters with the same names in the embodiments of the present technology have correspondence relationships. The present technology, however, is not limited to the embodiments, and can be implemented by making various modifications to the embodiments without departing from the scope of the present technology. Furthermore, effects described in the present specification are merely examples and not limited, and other effects may be provided.

Note that the present technology may also have the following configuration.
(1) A clock control device including:
   a first inverter to which a clock is input;
   a second inverter that shares an output with the first inverter and is inputted with a control signal; and
   an RC low-pass filter connected between the first inverter and a power supply.
(2) The clock control device according to (1), in which
   the RC low-pass filter includes:
   a resistor connected in series with the first inverter; and
   a capacitor connected to a connection point between the first inverter and the resistor.
(3) The clock control device according to (2), in which
   the resistor is provided on each side of a power supply of the first inverter.
(4) The clock control device according to (2), in which
   the resistor is provided on one side of a power supply of the first inverter.
(5) The clock control device according to any one of (2) to (4), in which
   the capacitor is connected in parallel with the first inverter.
(6) The clock control device according to any one of (2) to (4), in which
   the capacitor is connected in parallel with a series circuit of the first inverter and the resistor.
(7) The clock control device according to any one of (2) to (6), in which
   the resistor is a resistance element, an on-resistor of a field effect transistor, or a series circuit of the resistance element and the on-resistor of the field effect transistor.
(8) The clock control device according to any one of (1) to (7), in which
   a duty cycle adjust (DCA) circuit includes the first inverter, the second inverter, and the RC low-pass filter, and
   the DCA circuit is connected in a plurality of stages.
(9) The clock control device according to (8), in which
   a differential control signal is used as a control signal of two of the DCA circuits connected in the plurality of stages.
(10) The clock control device according to any one of (1) to (7), in which
   a DCA circuit includes the first inverter, the second inverter, and the RC low-pass filter, and
   the DCA circuit is connected in one stage.
(11) The clock control device according to any one of (1) to (10), further including:
   a differentiation circuit configured to differentiate an output of the second inverter;
   an amplifier configured to generate the control signal on the basis of a differentiation output that is output from the differentiation circuit; and
   a low-pass filter connected to an input of the amplifier.
(12) The clock control device according to (11), in which
   the low-pass filter includes:
   a filter resistor in series with an input of the amplifier; and
   a filter capacitor that is in parallel with an input of the amplifier and is connected to a power supply or ground of the first inverter or both the power supply and the ground.
(13) The clock control device according to (11) or (12), further including
   a local low-pass filter connected to a gate input of a field effect transistor that is used for the second inverter.
(14) A clock control device including:
   a first inverter to which a clock is input;
   a second inverter that shares an output with the first inverter and is inputted with a control signal;
   a differentiation circuit configured to differentiate an output of the second inverter;
   an amplifier configured to generate the control signal on the basis of a differentiation output that is output from the differentiation circuit; and
   a low-pass filter connected to an input of the amplifier.
(15) The clock control device according to (14), in which
   the low-pass filter includes:
   a filter resistor in series with an input of the amplifier; and
   a filter capacitor that is in parallel with an input of the amplifier and is connected to a power supply or ground of the first inverter or both the power supply and the ground.
(16) The clock control device according to (14) or (15), further including
   a local low-pass filter connected to a gate input of a field effect transistor that is used for the second inverter.
(17) The clock control device according to any one of (14) to (16), in which
   a DCA circuit includes the first inverter and the second inverter, and
   the DCA circuit is connected in a plurality of stages.
(18) The clock control device according to (17), in which
   a differential control signal is used as a control signal of two of the DCA circuits connected in the plurality of stages.
(19) The clock control device according to any one of (14) to (16), in which
   a DCA circuit includes the first inverter and the second inverter, and
   the DCA circuit is connected in one stage.

### REFERENCE SIGNS LIST

100, 110A, 110B, 120A, 120B, 130, 131 to 135, 232, 233 Inverter
101, 102 DCA circuit
103 Differentiation circuit
104, 105 Low-pass filter
106 Amplifier
111, 112, 115, 116, 121, 122, 125, 126 P-channel field effect transistor
113, 114, 117, 118, 123, 124, 127, 128 N-channel field effect transistor
211, 212, 221, 222 Resistance element
213, 223 Capacitor
231 Transmission gate

1. A clock control device comprising:
a first inverter to which a clock is input;
a second inverter that shares an output with the first inverter and is inputted with a control signal; and
an RC low-pass filter connected between the first inverter and a power supply.

2. The clock control device according to claim 1, wherein
the RC low-pass filter includes:
a resistor connected in series with the first inverter; and
a capacitor connected to a connection point between the first inverter and the resistor.

3. The clock control device according to claim 2, wherein
the resistor is provided on each side of a power supply of the first inverter.

4. The clock control device according to claim 2, wherein
the resistor is provided on one side of a power supply of the first inverter.

5. The clock control device according to claim 2, wherein
the capacitor is connected in parallel with the first inverter.

6. The clock control device according to claim 2, wherein
the capacitor is connected in parallel with a series circuit of the first inverter and the resistor.

7. The clock control device according to claim 2, wherein
the resistor is a resistance element, an on-resistor of a field effect transistor, or a series circuit of the resistance element and the on-resistor of the field effect transistor.

8. The clock control device according to claim 1, wherein
a duty cycle adjust (DCA) circuit includes the first inverter, the second inverter, and the RC low-pass filter, and
the DCA circuit is connected in a plurality of stages.

9. The clock control device according to claim 5, wherein
a differential control signal is used as a control signal of two of the DCA circuits connected in the plurality of stages.

10. The clock control device according to claim 1, wherein
a DCA circuit includes the first inverter, the second inverter, and the RC low-pass filter, and
the DCA circuit is connected in one stage.

11. The clock control device according to claim 1, further comprising:
a differentiation circuit configured to differentiate an output of the second inverter;
an amplifier configured to generate the control signal on a basis of a differentiation output that is output from the differentiation circuit; and
a low-pass filter connected to an input of the amplifier.

12. The clock control device according to claim 11, wherein
the low-pass filter includes:
a filter resistor in series with an input of the amplifier; and
a filter capacitor that is in parallel with an input of the amplifier and is connected to a power supply or ground of the first inverter or both the power supply and the ground.

13. The clock control device according to claim 11, further comprising
a local low-pass filter connected to a gate input of a field effect transistor that is used for the second inverter.

14. A clock control device comprising:
a first inverter to which a clock is input;
a second inverter that shares an output with the first inverter and is inputted with a control signal;
a differentiation circuit configured to differentiate an output of the second inverter;
an amplifier configured to generate the control signal on a basis of a differentiation output that is output from the differentiation circuit; and
a low-pass filter connected to an input of the amplifier.

15. The clock control device according to claim 14, wherein
the low-pass filter includes:
a filter resistor in series with an input of the amplifier; and
a filter capacitor that is in parallel with an input of the amplifier and is connected to a power supply or ground of the first inverter or both the power supply and the ground.

16. The clock control device according to claim 14, further comprising
a local low-pass filter connected to a gate input of a field effect transistor that is used for the second inverter.

17. The clock control device according to claim 14, wherein
a DCA circuit includes the first inverter and the second inverter, and
the DCA circuit is connected in a plurality of stages.

18. The clock control device according to claim 17, wherein
a differential control signal is used as a control signal of two of the DCA circuits connected in the plurality of stages.

19. The clock control device according to claim 14, wherein
a DCA circuit includes the first inverter, the second inverter, and the RC low-pass filter, and
the DCA circuit is connected in one stage.
